(19) United States
(12) Patent Application Publication
(10) Pub. No.: US 2025/0355347 A1
(43) Pub. Date: Nov. 20, 2025

(54) IMPRINTING TECHNIQUES IN NANOLITHOGRAPHY FOR OPTICAL DEVICES

(71) Applicant: Magic Leap, Inc., Plantation, FL (US)

(72) Inventors: Vikramjit SINGH, Pflugerville, TX (US); Marlon Edward MENEZES, Austin, TX (US); Shuqiang YANG, Austin, TX (US); Kang LUO, Austin, TX (US); Matthew TRAUB, Plantation, FL (US); Frank Y. XU, Austin, TX (US); Yingnan LIU, Plantation, FL (US); Satish SADAM, Round Rock, TX (US); Brandon Michael-James BORN, Sunnyvale, CA (US); Qizhen XUE, Austin, TX (US); Victor Kai LIU, West Point, CA (US)

(21) Appl. No.: 18/871,381

(22) PCT Filed: Jun. 3, 2022
(86) PCT No.: PCT/US2022/032239

§ 371 Date: Dec. 3, 2024

(51) Int. Cl. G03F 7/00

(52) U.S. Cl. CPC G03F 7/0002; G03F 7/0005

(57) ABSTRACT

This disclosure generally describes methods and systems for fabrication of high-quality surface relief waveguides for eyepieces. In particular, this disclosure describes techniques for manufacturing waveguides having surface relief features, such as diffractive gratings to achieve various optical effects, using nanolithographic imprinting techniques that reduce or eliminate the presence of gaps in the imprinted features through use of optimized drop patterns for dispensing photoresist. Moreover, the disclosure also describes techniques for manufacturing surface relief waveguides having a gradation, e.g., a substantially continuous grade or slope, between zones that have different residual layer thicknesses of the dispensed photoresist, and/or between zones having surface features of different height (or depth). Such gradation can reduce or eliminate adverse optical effects that may be caused by a more abrupt transition between zones, and increase the optical efficiency of the completed waveguide.

### TECHNICAL FIELD

The implementations described herein generally relate to systems and methods for fabricating surface relief waveguides for eyepieces, and to the optical devices created thereby.

### BACKGROUND

When manufacturing waveguides, eyepieces, and other types of optical devices, performance considerations can be important. For example, minor flaws in the manufactured device can have disproportionate effects on the optical performance of the device, leading to reduced optical power, light loss, artifacts, and so forth. Performance considerations may be balanced against costs of manufacturing the device, such as the costs of the component materials, fabrication, testing, and so forth. Thus, manufacturers of high performance optical devices have traditionally pursued various techniques that increase the quality of the manufactured device while avoiding excessive increases to the costs of manufacture.

### SUMMARY

This disclosure generally describes methods and systems for fabrication of high-quality surface relief waveguides for eyepieces. In particular, this disclosure describes techniques for manufacturing waveguides having surface relief features, such as diffractive gratings to achieve various optical effects, using nanolithographic imprinting techniques that reduce or eliminate the presence of gaps in the imprinted features. Moreover, the disclosure also describes techniques for manufacturing surface relief waveguides having a gradation, e.g., a substantially continuous grade or slope, between zones that have different residual layer thicknesses of the dispensed photoresist, and/or between zones having surface features of different height (or depth). Such gradation can reduce or eliminate adverse optical effects that may be caused by a more abrupt transition between zones, and increase the optical efficiency of the completed waveguide.

Implementations include a method performed by a system for manufacturing optical devices, the method comprising determining a dispense pattern to dispense drops of photoresist to form one or more surface features on at least one surface of a substrate, wherein determining the drop pattern includes: determining a grid of available drop locations, based at least partly on one or more constraints on the drop locations, wherein the one or more constraints are based on a configuration of one or more of: i) a dispenser component of the system, which dispenses the drop of photoresist, or ii) a stage component of the system, which stabilizes the substrate during dispensing; for each of a plurality of candidate dispense patterns, predict a spread pattern of the drops dispensed according to the respective candidate dispense patterns, wherein each of the plurality of candidate dispense patterns includes a subset of the available drop locations, and wherein the spread pattern is predicted based at least partly on the one or more surface features to be formed on the at least one surface of the substrate; and determining the dispense pattern that corresponds to an optimal spread pattern from among the plurality of spread patterns predicted based on the plurality of candidate dispense patterns; dispensing the drops of photoresist, according to the dispense pattern, onto the at least one surface of the substrate or onto a template usable to mold the one or more surface features; applying the template to mold the dispensed photoresist into the one or more surface features on the at least one surface of the substrate; curing the dispensed photoresist to form the one or more surface features; and singulating the substrate to create an optical device that includes the one or more surface features.

In some implementations, the substrate is composed of a glass or a polymer.

In some implementations, the photoresist is a polymer fluid.

In some implementations, curing the photoresist includes one or more of applying ultraviolet radiation to the dispensed photoresist, or applying heat to the dispensed photoresist.

In some implementations, the one or more surface features include one or more diffraction gratings.

In some implementations the one or more surface features are on one surface of the substrate.

In some implementations, the one or more surface features are on both surfaces of the substrate.

In some implementations, the one or more diffraction gratings include one or more of an in-coupling grating (ICG), an orthogonal pupil expander (OPE), an exit pupil expander (EPE), or a combined pupil expander (CPE).

In some implementations, the one or more surface features include non-diffractive patterns.

In some implementations, the one or more surface features include an anti-reflective pattern.

In some implementations, the one or more constraints include one or more of the following: a number of nozzles of the dispenser component, a spacing between the nozzles of the dispenser component, and a range of dispense frequencies of the nozzles of the dispenser component.

In some implementations, the one or more constraints include one or more of the following: a range of movement speeds of the stage component, and available directions of movement of the stage component.

In some implementations, determining the dispense pattern that corresponds to the optimal spread pattern includes identifying the optimal spread pattern that minimizes one or more of the following: a number of void gaps in the spread pattern, a size of the void gaps in the spread pattern, and a total volume of the void gaps in the spread pattern.

In some implementations, the at least one surface of the substrate includes a first zone and a second zone that is non-overlapping with the first zone; and the one or more surface features include a first set of surface features in the first zone and a second set of surface features in the second zone.

In some implementations, the first set of surface features includes a first residual layer of the photoresist having a first residual layer thickness (RLT) in the first zone; and the second set of surface features includes a second residual layer of the photoresist having a second RLT in the second zone, the second RLT being different than the first RLT.

In some implementations, the at least one surface of the substrate includes a third zone between the first zone and the second zone; and the third zone includes a third residual layer of the photoresist having a gradated RLT that varies continuously from the first RLT near the boundary of the third zone with the first zone to the second RLT near the boundary of the third zone with the second zone.

In some implementations, the first set of surface features includes first nanostructures having a first height relative to the at least one surface; and the second set of surface features includes second nanostructures having a second height relative to the at least one surface.

In some implementations, the at least one surface of the substrate includes a third zone between the first zone and the second zone; and the third zone includes third nanostructures having a height that varies continuously from the first height near the boundary of the third zone with the first zone to the second height near the boundary of the third zone with the second zone.

In some implementations, the optical device is a waveguide.

Implementations include an optical device comprising: a substrate; and surface features formed from a photoresist dispensed onto at least one surface of the substrate, the surface features including: a first set of surface features in a first zone of the at least one surface of the substrate, wherein the first set of surface features have a first height; a second set of surface features in a second zone of the at least one surface of the substrate, wherein the second zone is non-overlapping with the first zone, and wherein the second set of surface features have a second height that is different than the first height; and a third set of surface features in a third zone of the at least one surface of the substrate, wherein the third zone is between the first zone and the second zone, and wherein the third set of surface features have a varying height that varies continuously from the first height near the boundary of the third zone with the first zone to the second height near the boundary of the third zone with the second zone.

In some implementations, the first set of surface features includes a first residual layer of the photoresist having the first height that is a first residual layer thickness (RLT) in the first zone; the second set of surface features includes a second residual layer of the photoresist having the second height that is a second RLT in the second zone, the second RLT being different than the first RLT; and the third set of surface features includes a third residual layer of the photoresist having the varying height that is a gradated RLT that varies continuously from the first RLT near the boundary of the third zone with the first zone to the second RLT near the boundary of the third zone with the second zone.

In some implementations, the first set of surface features includes first nanostructures having the first height relative to the at least one surface; the second set of surface features includes second nanostructures having the second height relative to the at least one surface; and the third set of surface features includes third nanostructures having the varying height that varies continuously from the first height near the boundary of the third zone with the first zone to the second height near the boundary of the third zone with the second zone.

In some implementations, the surface features include one or more diffraction gratings.

In some implementations, the one or more diffraction gratings include one or more of an in-coupling grating (ICG), an orthogonal pupil expander (OPE), an exit pupil expander (EPE), or a combined pupil expander (CPE).

In some implementations, the substrate is composed of a glass or a polymer.

In some implementations, the photoresist is a polymer fluid.

In some implementations, the optical device is a waveguide.

Implementations include a method for manufacturing an optical device, the method comprising: determining a dispense pattern to dispense drops of photoresist to form surface features on at least one surface of a substrate; dispensing the drops of photoresist, according to the dispense pattern, onto the at least one surface of the substrate or onto a template usable to mold the surface features; applying the template to mold the dispensed photoresist into the surface features on the at least one surface of the substrate; curing the dispensed photoresist to form the surface features; and singulating the substrate to create the optical device that includes the surface features; wherein the surface features include: a first set of surface features in a first zone of the at least one surface of the substrate, wherein the first set of surface features have a first height; a second set of surface features in a second zone of the at least one surface of the substrate, wherein the second zone is non-overlapping with the first zone, and wherein the second set of surface features have a second height that is different than the first height; and a third set of surface features in a third zone of the at least one surface of the substrate, wherein the third zone is between the first zone and the second zone, and wherein the third set of surface features have a varying height that varies continuously from the first height near the boundary of the third zone with the first zone to the second height near the boundary of the third zone with the second zone.

In some implementations, the first set of surface features includes a first residual layer of the photoresist having the first height that is a first residual layer thickness (RLT) in the first zone; the second set of surface features includes a second residual layer of the photoresist having the second height that is a second RLT in the second zone, the second RLT being different than the first RLT; and the third set of surface features includes a third residual layer of the photoresist having the varying height that is a gradated RLT that varies continuously from the first RLT near the boundary of the third zone with the first zone to the second RLT near the boundary of the third zone with the second zone.

In some implementations, the first set of surface features includes first nanostructures having the first height relative to the at least one surface; the second set of surface features includes second nanostructures having the second height relative to the at least one surface; and the third set of surface features includes third nanostructures having the varying height that varies continuously from the first height near the boundary of the third zone with the first zone to the second height near the boundary of the third zone with the second zone.

In some implementations, the surface features include one or more diffraction gratings.

In some implementations, the one or more diffraction gratings include one or more of an in-coupling grating (ICG), an orthogonal pupil expander (OPE), an exit pupil expander (EPE), or a combined pupil expander (CPE).

In some implementations, the optical device is a waveguide.

In some implementations, the substrate is composed of a glass or a polymer.

In some implementations, the photoresist is a polymer fluid.

In some implementations, curing the photoresist includes one or more of applying ultraviolet radiation to the dispensed photoresist, or applying heat to the dispensed photoresist.

In some implementations, the method further includes etching at least one of the surface features, after the curing, to modify the at least one of the surface features.

In some implementations, the etching modifies one or more of the first height in the first zone, the second height in the second zone, or the varying height in the third zone.

In some implementations, the method includes a (e.g., post-processing) step of etching into the substrate or into a film coating on the substrate.

In some implementations, the method includes a (e.g., post-processing) step of deposition of a film over the pattern on the substrate to define a replication template and/or the optical device in relation to a waveguide, providing that, once the pattern is defined with the master pattern and drop pattern (e.g., for RLT), the pattern can be further replicated into other substrates or films for further replication or fabrication as an optical device (e.g., waveguide).

Implementations include a method of creating a template for imprinting, the method comprising: providing a carrier substrate with an overlay of blank (e.g., oxide or nitride) material; dispensing drops of photoresist onto the overlay according to a drop pattern; imprinting the photoresist to provide a pattern on the substrate, the pattern including a graded RLT; and etching (e.g., dry etching) the pattern into a final pattern, wherein the final pattern has a substantially flat upper extent.

Implementations include a method of creating a template for imprinting, the method comprising: providing a carrier substrate with an overlay of blank (e.g., oxide or nitride) material; creating an area of (e.g., spincoated) photoresist on the substrate that is not to be etched or removed in subsequent steps; removing a portion of the photoresist (e.g., using wet etching, dry etching, and/or stripping); creating a dome or inverse dome shaped deposition profile in the overlay using controlled plasma; performing blank etching to reduce the remaining portion of the overlay to a particular depth; performing photolithography to create features in the carrier substrate; performing lithography to provide a pattern (e.g., ICG pattern); and etching the pattern and stripping at least a portion of the resist to provide the template.

Other features and advantages are apparent from the following detailed description and figures, and from the claims.

### BRIEF DESCRIPTION OF THE DRAWINGS

FIG. 1 depicts an example system for manufacturing optical devices.

FIGS. 2A and 2B depict schematics of example template configuration and operation.

FIG. 3 depicts a flow diagram of an example process for determining a drop pattern for use in manufacturing optical devices.

FIG. 4 depicts a schematic of an example grid for determining a droplet pattern.

FIGS. 5A and 5B respectively depict an example drop pattern and an example of a fluid dispersion pattern based on the drop pattern.

FIG. 6 depicts a flow diagram of an example process for creating surface feature(s) on a substrate.

FIGS. 7A-7D show schematics of an example template and an example grating pattern created through application of the template.

FIGS. 8A and 8B show schematics of example grating patterns.

FIGS. 9-12 depict diagrams of example processes for creating a template.

FIG. 13 depicts an example computing system.

### DETAILED DESCRIPTION

This disclosure describes various implementations of methods and systems for manufacturing high-quality optical devices. The optical devices created using the techniques described herein are suitable for use in virtual reality (VR), augmented reality (AR), and/or mixed reality (MR) systems, and/or other suitable optical applications. For example, the optical devices can be incorporated into wearable (e.g., head-mountable) display systems that provide an AR experience to the wearer. In such systems, the eyepieces can be transparent to allow the wearer to view the physical environment while the waveguide(s) of the eyepieces convey light used to presented graphical objects as an overlay to the view of the physical environment. In some examples, the waveguide(s) are configured to presented the graphical objects at a plurality of depth planes, such that the wearer can perceive the graphical objects as if the objects were at a particular distance from the wearer, e.g., at different depth planes or focal distances. In some examples, the waveguides can be arranged in a waveguide stack, in which different ones of the waveguides are configured to present graphical objects at different depth planes and/or to convey light of different wavelength ranges (e.g., red, green, and blue).

The optical devices include high-quality surface relief waveguides that can be used in eyepieces, alone or in stacked configurations of multiple waveguides. Optical features in the surface relief waveguides have high nanofeature fidelity and high uniformity in residual layer thickness (RLT) in one or more zones that may have differing requirements for resist volume given the surface features (e.g., of diffraction grating(s)) to be created in each zone. In some implementations, the features may be manufactured through the dispensation, patterning, and curing of a high refractive index nanoimprintable fluid, which may also be described as a photoresist, resist, or resin. The features can be created on one surface or both surfaces of a broad, substantially flat substrate that is transparent, and that operates as a waveguide to convey light through total internal reflection (TIR).

The surface features created on one or more surfaces of the substrate can include diffraction gratings that are optically functional to affect the light passing through the substrate. Such diffraction gratings can include, but are not limited to, an in-coupling grating (ICG), an out-coupling grating (OCG), an orthogonal pupil expander (OPE), an exit pupil expander (EPE), a combined pupil expander (CPE), and/or other types of gratings. The substrate, and the manufactured eyepiece, can include any suitable number and type of such gratings in any suitable combination to achieve the desired optical performance.

The substrate can be composed of any suitable material, including various suitable glasses and polymers. For example, the substrate can be composed of an inorganic amorphous material (e.g., dense tantalum flint glass TADF55, quartz, etc.), a crystalline material (e.g., LiNbO3, LiTaO3, SiC, etc.), high index polymers (e.g., containing sulfur, aromatic groups, etc.), and/or other polymer materials such as polycarbonate (PC), polyethylene terephthalate (PET), and so forth.

Implementations described herein employ a drop-on-demand, controlled volume dispensing technique for dispensing a fluid onto a substrate with precise control of the volume of the drops of fluid (also described as droplets) being dispensed, and the location on the substrate onto which they are dispensed. The dispensed fluid can then be imprinted to create a patterned optical device suitable for use in AR systems, MR systems, and/or other suitable optical applications.

The fluid may be dispensed onto an optically transparent substrate that operates as a waveguide, and the dispensed fluid can be imprinted with a template and then cured to create the desired nanofeatures (e.g., diffraction gratings) on one or more surfaces of the transparent substrate. As used herein, optically transparent generally refers to the physical property of allowing light to pass through a material without being scattered or absorbed.

As used herein, total thickness variation (TTV) refers to the difference between the maximum and minimum values of the thickness of a substrate in a series of point measurements across a dimension of a substrate. For a substrate having a patterned surface on which diffraction gratings have been created, the TTV refers to an approximation assessed by ignoring contributions of pattern features to the thickness. For example, a thickness (or height) of a typical feature on a patterned substrate may be in a range of approximately 10 nanometers (nm) to 150 nm. That thickness is governed by the trench depth of the template, which can vary by 10% (e.g., 1 nm to 15 nm). The TTV of an unpatterned substrate typically exceeds 100 nm, and is sometimes on the order of microns. Thus, the additional variation in thickness of a patterned substrate introduced by the pattern features is negligible, and can be ignored as an approximation. Accordingly, the thickness of a patterned substrate assessed at a location that includes a protrusion can be approximated by subtracting a given feature thickness from the assessed thickness to yield an adjusted thickness, while thickness of a patterned substrate assessed at a location without a protrusion is unchanged. That is, the adjusted (e.g., reduced) thickness of a feature area and a native thickness of an unpatterned area can be used to calculate TTV for a substrate having a patterned surface. The low TTV values described herein result at least in part from flat optical grade glass substrates, polished to meet a desired flatness, as well as methods described herein to minimize or reduce uneven material shrinkage during curing. The low TTV can also be imparted to an inorganic material substrate through extrusion. In addition the low TTV can also be imparted to a polymer substrate material and achieved from mold surfaces while molding (e.g., injection molding, ultraviolet (UV) or thermal molding, extrusion, etc.) such substrates from base materials consisting of high index polymers (e.g., containing sulfur, aromatic groups, etc.) and other polymer materials such as polycarbonate.

As used herein, RLT refers to a thickness of the (e.g., polymer) photoresist deposited onto the substrate in regions where a surface feature (e.g., grating) is not present, and/or in regions where a surface feature is present but between the particular nanogeometry structures of the surface feature. The RLT may be substantially similar across the finished eyepiece, or different zones of the eyepiece may have different RLTs. In some implementations, there may be a substantially continuous and/or gradual variation of RLT across at least a portion of the eyepiece. In some implementations, different zones may have different RLTs, and there may be a continuous gradation (e.g., slope) of the RLT in transition areas from one zone having one RLT and another zone having a different RLT. Implementations described herein enable the RLT to be fine-tuned to achieve various desired optical performance characteristics in the finished eyepiece.

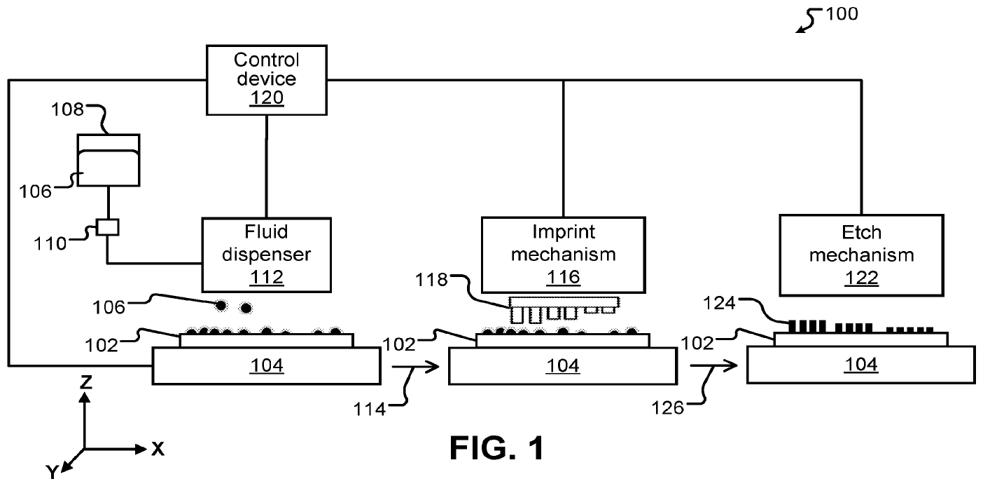

FIG. 1 depicts an example system 100 for manufacturing optical devices, by dispensing fluid 106 (e.g., nanoimprint photoresist fluid) onto a substrate 102, and imprinting the dispensed fluid 106 to create a pattern on the substrate 102. As shown in this example, the system 100 can include various components that perform various operations to manufacture an optical device, such as a waveguide or an eyepiece.

As shown in FIG. 1, the system 100 can operate on a substrate 102 while the substrate is supported by a stage 104. The stage 104 can also be described as a chuck. The substrate 102 may be composed of any suitable material such as glass or polymer. The substrate 102 may be in any suitable form, include a sheet, a wafer, a film, and so forth. In some examples, the portion of substrate 102 (e.g., a wafer) may include multiple regions that each correspond to an eyepiece to be cut out of the substrate 102 following other manufacturing steps to create the desired patterns (e.g., diffraction gratings) on one or more surfaces of the substrate 102.

The stage 104 may be configured to support the substrate 102 and stabilize the substrate 102 during fluid dispensing, imprinting, curing, etching, and/or other manufacturing operations. The stage 104 may be configured to secure the substrate 102 to the stage 104, such as through use of a vacuum pump to create suction that holds the substrate 102 to the stage 104. The stage 104 may be moveable to move between different stations of the manufacturing system 100, as in the example shown where the stage is moved from a fluid dispensing station to an imprinting station to an etching station, and so forth. The stage 104 may also be configured to move in various directions while in place in proximity (e.g., under) one of the stations. For example, if the stage 104 is holding the substrate 102 that has surfaces that are substantially planar and include X-and Y-axes, as shown, the stage 104 may be configured to move in the X-direction and/or the Y-direction under the station. In some implementations, the stage 104 may also be configured to be moveable in a Z-direction to increase or decrease the distance between the substrate 102 and the particular device performing on operation on the substrate 102 (e.g., the fluid dispenser 112, the imprint mechanism 116, the etch mechanism 122, etc.). In some implementations, the stage 104 is configured to support the substrate 102 by its edge such that both broad surfaces of the substrate 102 are accessible for such operations. In some implementations, the stage 104 can be configured to flip the substrate 102 in the Z-direction to make both, opposite sides of the substrate 102 available for fluid dispense, imprinting, curing, etching, and/or other operations.

A fluid dispenser 112 is configured to dispense drops (or droplets) of the fluid 106, such as resist, onto the substrate 102. The fluid dispenser 112 can include one or more printheads (or nozzles) that dispense (e.g., jet) the drops of the fluid 106. The fluid 106 is held in a reservoir 108, which is connected to the fluid dispenser 106 by one or more channels (e.g., tubes, conduits, etc.) of suitable type, material, and dimension. One or more fluid pumps 110 operate to circulate the fluid 106 between the reservoir 108 and the fluid dispenser 112. The system 100 can also include various other suitable devices, such as pumps, pressure sensors, flow sensors, filters, and so forth, arranged to provide a reliable flow of the fluid 106 to the fluid dispenser 112.

The fluid dispenser 112 may dispense a number of drops of the fluid 106 to particular locations on a surface of the substrate 102, at any suitable location and drop size or volume, during any suitable number of dispensing passes. The fluid 106 may be dispensed according to a determined drop pattern to optimize fluid 106 usage, minimize the presence of air gaps in the cured gratings, and/or precisely control the RLT of the dispensed fluid. Such drop patterns are described further below.

After fluid dispense, the stage 104 may move (114) to a next station, at which a template 118 is applied to the fluid 106 by an imprint mechanism 116. The template 118 may be applied to create the desired surface feature(s) 124 (e.g., grating(s)) on a surface of the substrate 102.

In some implementations, the fluid dispenser and imprinting are performed according to a drop-on-demand Jet and Flash Imprint Lithograph (J-FIL) technique to dispense the fluid 106 and imprint the desired pattern(s) into the fluid 106, to create surface feature(s) such as diffraction grating(s). Such techniques are described in U.S. Pat. No. 7,077,992, titled “Step and Repeat Imprint Lithography Processes,” the entirety of which is incorporated by reference into the present disclosure.

In some implementations, after imprinting, the stage 104 may move (126) to a next station, at which an etch mechanism performs one or more etching operations to modify the imprinted patterns. Such etching is described further below.

A control device 120 is communicatively coupled to various other devices of the system 100 that perform actions on the substrate 102 and to manufacture the optical device, including the stage 104, the fluid dispenser 112, the imprint mechanism 116, the etch mechanism 122, and so forth. The control device 120 can send signals to the various other devices to control their operations. In some implementations, the control device 120 is a computing device of any suitable type, which includes at least one processor and memory. The memory can store a computer program that includes instructions which, when executed by the at least one processor, cause the processor(s) to perform operations to control device(s) of the system 100 during the manufacturing process. The control device 120 may be any suitable type of computing device, such as a personal computer, and may communicate with other computing devices to receive instructions, provide data, etc.

Although FIG. 1 shows an example of a system 100 that includes a single fluid dispenser 112, other implementations are possible. For example, the system 100 may include multiple fluid dispensers 112 (e.g., printheads) to improve throughput of the system 100 and/or dispense fluid 106 additional locations on the substrate 102. The system 100 may similarly include multiple imprinting stations, each with an associated imprint mechanism 116 and/or template 118.

Implementations support the use of various suitable types of photoresist fluid 106. In some implementations, the resist is a polymer-based resin with incorporated nanoparticles (NPs) of a higher index material. Alternatively, the resist can be a polymer-based resin without incorporated NPs. Incorporation of NPs may increase the overall refractive index of the material, which provides advantages in more closely matching the refractive index of the substrate as described herein. However, incorporation of NPs may also cause Rayleigh scattering of light in the resist. Accordingly, the choice of using a resist that includes NPs, or that omits NPs, may be based on a balancing of considerations, e.g., higher index vs. more scattering. For example, a resist with refractive index 1.6 or 1.7, and without NPs, may provide optimal performance that provides for a higher index (e.g., closer to that of the substrate) while avoiding the scattering that would be caused by the presence of NPs.

Organic (meth)acrylate monomers and oligomers typically have a refractive index of approximately 1.5 at a 532 nm wavelength. Sulfur atoms and aromatic groups, which both have higher polarizability, can be incorporated into these acrylate components to boost the refractive index of the formulation. This effect is limited due to the fluid viscosity restriction of less 20-25 cP for the inkjet process, and by the refractive index upper limit of the sulfur containing molecules. This approach yields jettable and imprintable resists with a refractive index as high as 1.72 at 532 nm wavelengths of light.

Incorporating inorganic nanoparticles (NP) such as ZrO2 and TiO2 can boost refractive index significantly further. Pure ZrO2 and TiO2 crystals can reach 2.2 and 2.4 -2.6index at 532 nm respectively. For the preparation of optical nanocomposites of acrylate monomer and inorganic nanoparticle, the particle size is smaller than 10 nm to avoid excessive Rayleigh scattering. Due to its high specific surface area, high polarity, and incompatibility with the cross-linked polymer matrix, a ZrO2 NP has a tendency to agglomerate in the polymer matrix. Surface modification of NPs can be used to overcome this problem. In this technique, the hydrophilic surface of ZrO2 is modified to be compatible with organics, thus enabling the NP to be uniformly mixed with the polymer. Such modification can be done with silane and carboxylic acid containing capping agents. One end of the capping agent is bonded to ZrO2 surface; the other end of capping agent either contains a functional group that can participate in acrylate crosslinking or a non-functional organic moiety. Examples of surface modified sub-10 nm ZrO2 particles are those supplied by Pixelligent Technologies™ and Cerion Advanced Materials™. These functionalized nanoparticles are typically sold uniformly suspended in solvent as uniform blends, which can be combined with other base materials to yield resist formulations with jettable viscosity and increased refractive index.

The system 100 may also include other stations and other devices that perform additional operations on the substrate 102, as the stage 104 moves the substrate 102 from station to station. In some implementations, the system 100 includes a station for curing the dispensed fluid 106 after it has been molded into the desired forms at the imprinting station. Such curing may be through any suitable technique, according to the particular fluid 106 being used, such as the application of heat, radiation (e.g., UV light), and/or pressure. The system 100 can also include a station that singulates (e.g., cuts) the substrate 102 into desired eyepiece shape(s) for the optical device. The system 100 can also include a station that inspects the substrate 102 at one or more stages in the manufacture, such as through operation of an imaging camera.

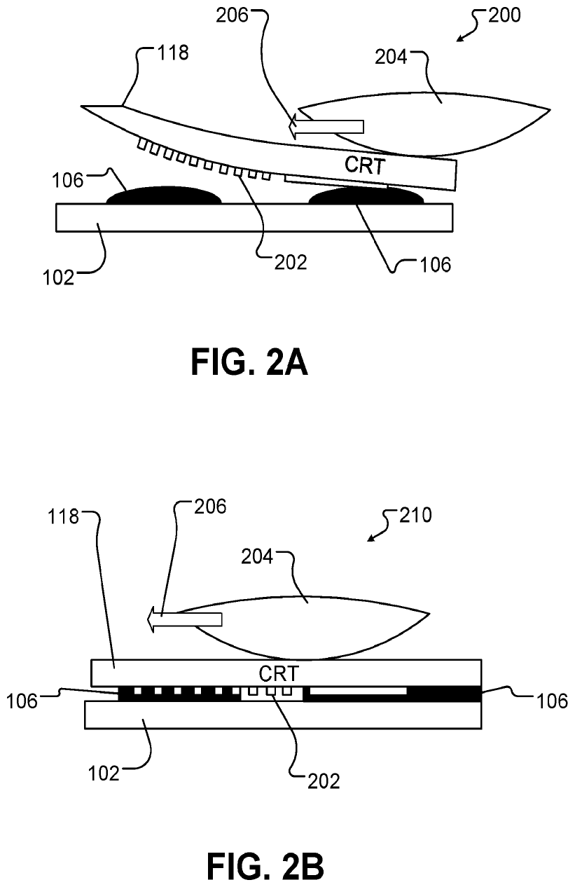

FIGS. 2A and 2B depict schematics of example template configuration and operation. Schematic 200 shows the substrate 102 with dispensed drops of fluid 106 on its surface, and a template 118 is being applied to form the fluid 106 into the desired grating(s) on the surface of the substrate 102. As shown, the template includes a (e.g., negative) form of the grating pattern 202 to be applied. In this example, the template 118 is a flexible, rollable template that is applied to the substrate 102 through operation of a roller device 204 that may be a component of the imprint mechanism 116. The roller device 204 can move in a direction 206 substantially parallel to the surface of the substrate 102, to press the template onto the substrate 102 and mold the dispensed fluid 106 into the desired nanogeometry for grating(s). Schematic 210 shows a subsequent state, in which the template 118 is fully pressed against the substrate 102 and the grating(s) have been formed by the application of the template.

In some implementations, the template is a Coated Resist Template (CRT). The template can be manufactured by imprinting onto any suitable substrate, including plastic (e.g., PC, PET, etc.), glass, silicon, and so forth. The substrate can be in the form of a wafer, sheet, web roll, or other suitable format. Once the surface is imprinted (e.g., after an appropriate adhesion surface treatment), the patterned polymer resist can be conformally coated with a material such as SiO₂, Al₂O₃, Al, Ag, TiN, Cr, through depositing using any suitable technique (e.g., PVD sputter, CVD-ALD, APPECVD, etc.). This patterned polymer can now be used as a template or mold for nanoimprinting. The coated surface may also be treated with release fluoropolymer materials to improve release performance during demolding during the imprint process (e.g., when the template is separated from the waveguide substrate onto which the diffraction gratings are being formed by the template application).

Although this example depicts a rollable template configuration for use in the imprinting step, implementations are not so limited. Other types of templates such as a template 118 that presses downward (e.g., in the Z-direction in FIG. 1) onto the surface of the substrate 102 instead of making a lateral movement in the X-Y plane parallel to the surface of the substrate 102. In some implementations, the template 118 has been etched or otherwise imprinted onto the surface of a cylindrical drum that imprints the desired pattern(s) into the fluid 106 as the drum rolls over the substrate and dispensed fluid 106. In such implementations, the imprint direction 106 can be perpendicular to the rotational axis of the cylinder. In some implementations, the template is applied spherically such that pressure is initially applied to press the template to the substrate at or near the center of the portion of substrate being imprinted (e.g., the wafer), and subsequently outward from the center.

Multiple eyepieces may be manufactured from a particular wafer of substrate. For example, six eyepieces may be made from a wafer (e.g., a 6-up configuration) or four eyepieces may be made from a wafer (e.g., a 4-up configuration). In some implementations, the fluid dispense step dispenses the fluid for all of the eyepieces on the wafer in one operation or set of operations. Alternatively, fluid dispense operation(s) can be performed separately for each eyepiece, with the stage rotating the substrate under the fluid dispenser between the dispense operations, to move a different eyepiece region under the dispenser. Similarly, the imprint step may be performed simultaneously for all the eyepieces on the wafer, using a template that is arranged to imprint all the eyepieces simultaneously. Alternatively, the template may be arranged to imprint a single eyepiece, and each eyepiece may be imprinted separately with the stage (or template) moving from eyepiece to eyepiece accordingly.

In some implementations, the fluid 106 is dispensed onto the template 116 instead of, or in addition to, being dispensed onto a surface of the substrate 102. The techniques described herein operate similarly in such implementations, with the drop pattern of fluid drops being dispensed onto the template 116 surface that includes (e.g., a negative of) the features to be imprinted onto the substrate 102.

### Drop Pattern Determination

Implementations provide techniques for determining a drop pattern for the dispense of the fluid 106 onto the substrate 102 (or onto the template) to create the desired surface feature(s) on the substrate 102. The drop pattern is determined such that non-fills (e.g., air gaps) are minimized or eliminated from the fluid 106 spread by application of the template 118, and accordingly minimized or eliminated from the surface features formed from the cured fluid. The drop pattern is also determined to provide controlled, and in some instances ultra-thin, RLT in the resulting waveguides.

During imprinting using previously available techniques, void defects may be created due to the entrapment of air in the resist during dispense and imprint. These defects are referred to as non-fills in nanolithography, and are areas (e.g., at least partly internal to the imprinted and cured nanofeatures) that are not filled with resist. The previous method for preventing such defects was to dispense extra volume of resist to the area, to ensure that all the gaps are filled in. Unfortunately, the extra volume may lead to undesirably large RLT, which may create adverse optical performance in the finished waveguide. Implementations determine a drop pattern that enables efficient filling of the grating pattern of the applied template, without needing to increase the volume of dispensed resist.

When the fluid front traps air as the template 118 is being applied, e.g., when the fluid 106 is being pressed between the substrate 102 and the template 118 (also referred to as a superstrate), and the air cannot vent out of the fluid 106 prior to curing, void defects (e.g., air gaps) can be created in the cured resist structures. The grating being created may have a grating direction that is an axis along which the grating pattern is arranged. For example, the grating may include long channels along the grating direction, separated by ridges. The void or non-fill defects may be more likely to be created when the grating direction is substantially perpendicular to the imprinting direction (e.g., the direction 206 in which the rolling device 204 is moving to apply the template 118), compared when the grating direction is parallel to the imprinting direction. In some instances, the non-fill defects may be more likely to be created when the grating direction is substantially parallel to the imprinting direction. Substantially perpendicular, or substantially parallel, can signify angular deviations from perpendicular or parallel that are within a suitable arc angle (e.g., within one degree, within five degrees, within ten degrees, etc.).

To address this problem and eliminate or mitigate the air gaps, implementations determine an optimal drop pattern that takes into account the spreading properties of the fluid 106 on the substrate 102, predicted according to the particular pattern being imprinted, the fluid and substrate properties, the imprint direction, and/or other variables. The drop spreading properties are related to the resist properties (e.g., viscosity), substrate surface properties, template properties (e.g., the grating(s) to be created), and imprinting conditions. For example, the spreading ratio can be similar for domed (e.g., convex or concave) glass and silicon substrates, with other variables kept constant, and flat glass can exhibit larger spreading ratios. Thus, for glass substrates of different TTV, the optimized drop patterns may be different. The spreading ratio can also vary for different imprint speeds (e.g., speed at which the template is applied). For example, the faster the imprinting, the harder it may be for air to escape, and the easier it may be for void defects to be formed.

The spreading ratio is defined as a ratio of the width of the spread ellipsoidal drop (e.g., lateral spread) to the length of the spread ellipsoidal drop (e.g., longitudinal spread). Alternatively, the ratio can be defined as the longitudinal spread over the lateral spread. If the lateral to longitudinal spread is known for a particular resist material over a particular substrate, and further based on knowledge of how the resist fluid spreads and/or interacts with the template (e.g., through capillary filling, etc.), such information can be used to modify drop patterns for imprinting in lithography techniques such as J-FIL.

The grating direction is the direction along (e.g., substantially parallel to) the long axis of features present in the imprinted gratings. The direction perpendicular to the grating direction is referred to as the lateral direction. In some implementations, the imprinting direction is the grating direction, but implementations support any imprinting direction at any angle relative to the grating direction. The imprinting direction may be in the lateral direction, to more effectively spread the fluid across the boundaries between channels. The distance between drops, or between different rows of drops, in the lateral direction is called lateral spreading distance. The smallest available such distance is referred to as the Minimum Lateral Spreading Distance (MLSD). This value may be constrained by the printhead geometry, e.g., the distance between nozzles of the fluid dispenser 112. A smaller MLSD can help to avoid void defects, given that the fluid tends to spread along the grating features (e.g., in the grating direction) and less easily spread across the grating features (e.g., in the lateral direction). To help the fluid merge in the lateral directions and eliminate air traps, a smaller MLSD can be used in the drop pattern. However, if the MLSD is too small, it may lead to a large separation between the drops in the grading direction, which may also cause defects. Accordingly, implementations model different drop patterns and enable selection of the drop pattern that results in an optimal spreading with minimal or no gaps. Optimal drop patterns also can lead to a reduction in the total volume of resist being dispensed (e.g., a 50% reduction compared to previous techniques), given that the optimal drop pattern enables drops to be placed to optimally fill the volume of the gratings and provide the desired RLT outside of the grated regions. Drop patterns for imprinting are further described in U.S. Pat. No. 8,119,052, titled “Drop Pattern Generation For Imprint Lithography,” the entirety of which is incorporated by reference into the present disclosure.

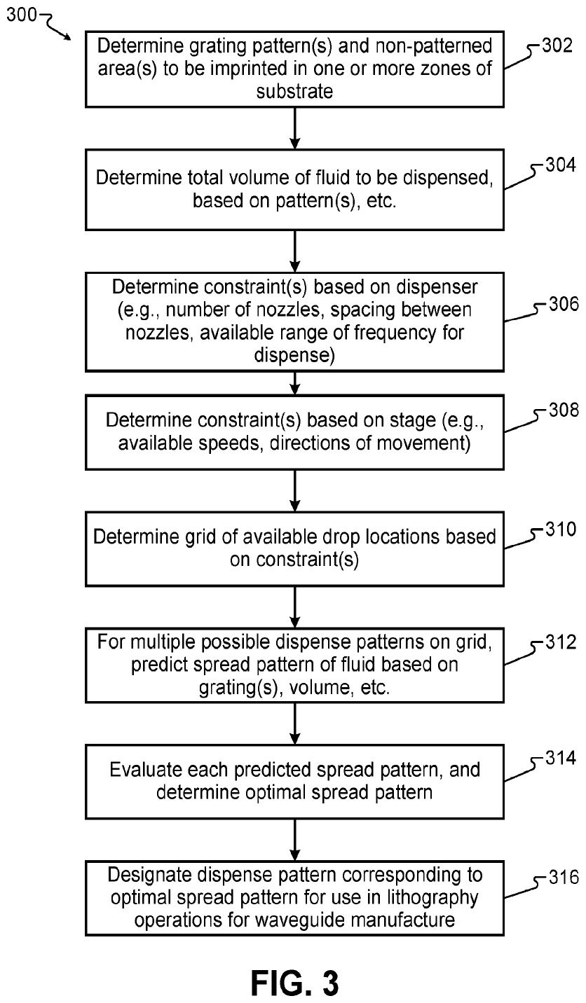

FIG. 3 depicts a flow diagram of an example process 300 for determining a drop pattern for use in manufacturing optical devices. Operations of the process may be performed by software executing on one or more suitable computing devices. The various operations can be performed in any suitable order. Some operations may be combined into a single operation. Operations may be performed serially and/or in parallel, as suitable for the particular operations.

At 302, the various grating pattern(s) and non-patterned area(s) to be created on the substrate 102 are determined. Such pattern(s) (or non-pattern(s)) may be present in one or more zones on the substrate 102.

At 304, a determination is made of the total volume of fluid to be dispensed, based on the volume of the grating pattern(s) to be filed as defined by the template, plus the region(s) of unpatterned areas that may receive resist of various thicknesses, along with the desired RLT in the patterned and/or unpatterned zone(s).

At 306, a determination is made of the various constraint(s) on the drop pattern that may be present based on the configuration of the fluid dispenser 112. Such constraints can include the number of nozzles of the dispenser, the spacing between the nozzles, and the available dispense frequency. The dispense frequency is the frequency at which a nozzle can dispense a drop (e.g., a firing frequency). In some examples, the dispense frequency can be specified as a range of frequencies. The range of dispense frequency may have a defined upper bound based on the dispenser configuration (e.g., as fast as it can fire), and no defined lower bound (or a lower bound of zero).

At 308, a determination is made of the various constraint(s) on the drop pattern that may be present based on the configuration of the stage 104, such as the available speed of movement of the stage 104 and available directions of movement. In some implementations, the information accessed at 302, 304, 306, and/or 308 may be input to the process as input parameters or otherwise specified.

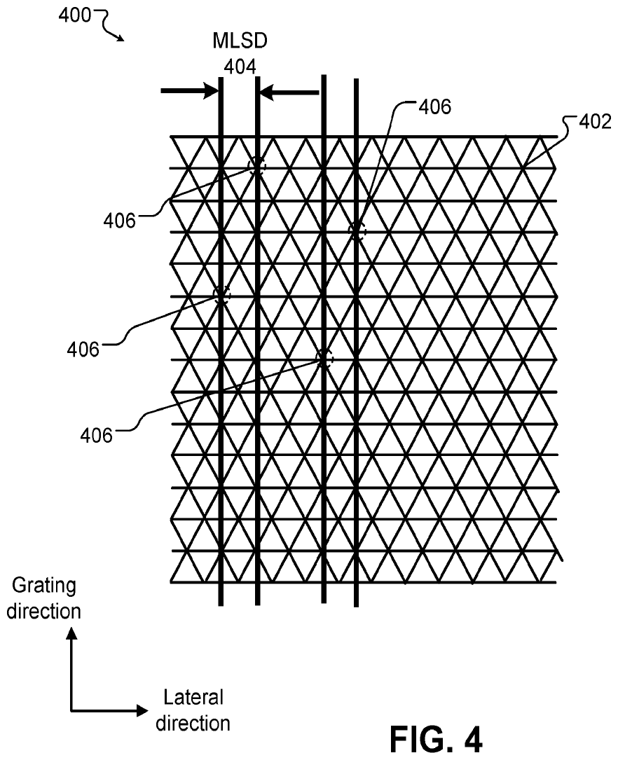

At 310, a grid is generated that specifies available drop locations based on the constraint(s) accessed at 306 and 308. An example of such a grid is shown in FIG. 4. Each vertex of the grid indicates a location on the substrate 102 at which the dispenser can dispense a drop of the fluid 106.

At 312, each of multiple possible drop patterns (e.g., dispense patterns) can be analyzed, and the process can execute to predict the spread pattern of the fluid 106 that is dispensed according to the respective drop pattern. This prediction can be made based on the particular drop pattern, along with the volume of fluid 106 to be dispensed, the particular geometry of the grating(s) to be created, the fluid properties of the fluid 106, the properties of the substrate 102 (e.g., coefficient of friction, etc.), and/or other variables. In some implementations, the process also takes into account the spread ratio of the drops as governed by which direction the fluid front moves (e.g., based on the template imprint direction) and spreads once the template starts pushing on drops over the surface of the template and substrate.

At 314, each predicted spread pattern from each analyzed drop pattern can be evaluated, and the optimal spread pattern can be identified. The optimal spread pattern can be the spread pattern that includes the fewest air gaps, smallest air gaps, and/or smallest total volume of air gaps. In some implementations, each spread pattern can be scored based on such a metric that takes into account number and/or size of air gaps, and the best scoring spread pattern can be designated as optimal.

At 316, the drop pattern corresponding to the optimal spread pattern is identified and designated as the drop pattern to be used for dispensing the fluid 106 prior to imprinting and curing, to create the desired surface features. In some implementations, the analysis to determine the best drop pattern can be performed manually through human examination of the various resulting spread patterns presented on a suitable display of a computing device. Alternatively, the algorithm can iteratively execute to search for the optimal spread pattern automatically, based on a calculated score as described above, and the drop pattern to be used can be automatically identified as the drop pattern corresponding to the optimal spread pattern.

FIG. 4 depicts a schematic of an example grid 400 for determining a droplet pattern. Each vertex of the grid 400, e.g., where lines meet, can be considered as a possible location for dispensing a drop onto the substrate 102 (or onto the template 118). As discussed above, the possible locations for dispensation are determined based on the configuration of the dispenser, such as the distance between nozzles and the available range of nozzle firing frequency, and the configuration of the stage, such as how quickly and in what direction the stage is able to move under the dispenser. Other factors may be taken into account as well, such as the number of passes that can be made with the stage at different positions under the dispenser. The MLSD 404 is shown as the distance horizontally (along the lateral direction) separately a vertical row of drop locations. The spacing along such a vertical row may be based on the firing frequency of the nozzle and the speed of the stage moving under the nozzle. In this example, four drop locations 406 have been selected for analysis by the process described in FIG. 3. These drop locations can be modeled to determine the resulting spread pattern as described above.

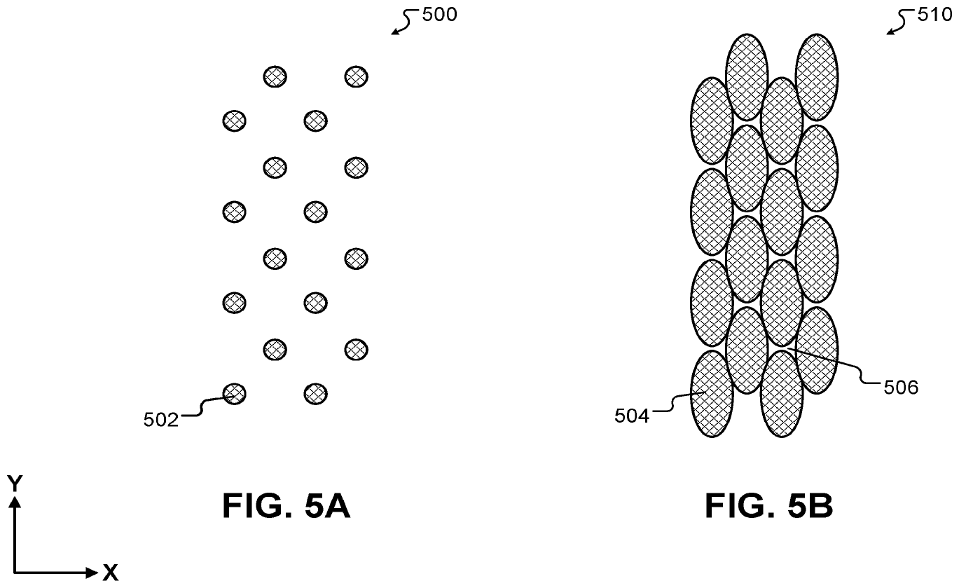

FIGS. 5A and 5B respectively depict an example drop pattern 500 and an example of a fluid dispersion pattern 510 that may result from the spreading of the drops of fluid 106 that have been dispensed according to the drop pattern, after application of the template 118. As shown in this example, each drop 502 may spread to an elongated shape 504 according to the particular geometry of the grating. The spreading of the various drops 502 may leave one or more air gaps 506 where the fluid 106 does not fill in. As discussed above, the techniques described herein reduce or eliminate the number and volume of such air gaps, to ensure optimal performance of the completed optical device.

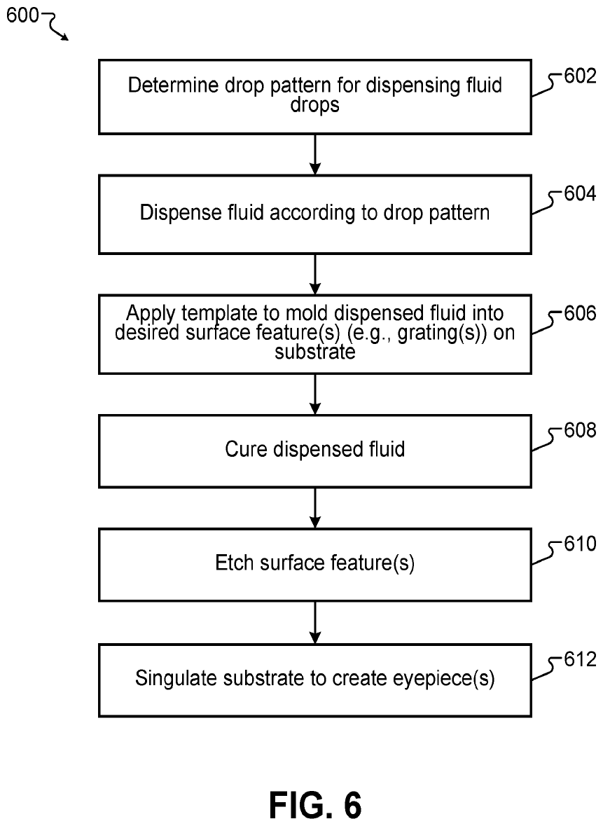

FIG. 6 depicts a flow diagram of an example process 600 for creating surface feature(s) on a substrate. Operations of the process may be performed by one or more components of the system 100, for example under control of the control device 120. The various operations can be performed in any suitable order. Some operations may be combined into a single operation. Operations may be performed serially and/or in parallel, as suitable for the particular operations.

At 602, the drop pattern is determined as described above. At 604, the fluid 106 is dispensed onto the substrate 102 according to the drop pattern. As discussed above, in some implementations the fluid 106 is dispensed onto the template 118 according to the drop pattern. At 606, the template 118 is applied to mold the dispensed fluid into the desired surface feature(s) (e.g., diffraction grating(s)) on one or more surfaces of the substrate. In implementations where the template is a rolled and/or flexible template, as in the example of FIGS. 2A and 2B, or a rolled cylindrical template as described above, the rolling direction may be in any suitable direction relative to the grating direction and/or the lateral direction.

In instances where the template is a cylindrically rolled template that is applied to the substrate, the fluid front of the drop spreading can be substantially linear (e.g., perpendicular to the imprint direction of the template). In some examples, the template is moved down vertically over the substrate to press onto the substrate (e.g., not rolled in cylindrically), and the drop spread fluid front can be more circular instead of a linear fluid front between the template and the substrate interface. In this instance, for determining the drop pattern design and placement, the drop spread ratio may be less dependent on the imprint direction given a specific nano- or micro-pattern to be applied during imprinting. For the imprint process with the template contacting the center of the wafer or close to center, the advantages include less dependency of the spreading ratio on the particular imprint direction (e.g., there is not one direction but more of a 360 degree outward imprinting action), and such techniques can help to maintain the optical performance equivalently over the eye pieces distributed in a pin wheel configuration (e.g., with rotational symmetry). In the case of an imprint process with the roller rolling from one end (e.g., the leading edge) to another end (e.g., the trailing edge), the eyepieces at different locations on the wafer may exhibit different performance characteristics in the final products.

At 608, the dispensed fluid is cured, using heat, UV light, pressure, and/or some other technique. At 610, in some implementations the imprinted and cured surface features can be etched to modify the surface feature(s) and/or fine-tune them into their final shape. Such etching is described in more detail below. At 612, the substrate 102 can be singulated (e.g., cut) to create the one or more eyepieces from the substrate 102.

As discussed herein the problem of air entrapment in the finished surface feature(s) is addressed through drop pattern optimization to determine a drop pattern that reduces or eliminates the presence of air gaps in the cured, dispensed photoresist formed into nanogeometric structures for diffraction grating(s). Determining the amount of fluid 106 needed is, at least partly, a geometry calculation, in which the volume of fluid is calculated as the fluid volume which is sufficient to form the desired surface feature(s), plus the volume to be deposited on non-grated portions of the substrate (if any), plus the desired RLT in one or more zones of the substrate 102.

Different drop pattern solutions may not all have a similar filling efficiency for filling the desired geometry of the gratings. In the gratings, the drops tend to flow along the grating (e.g., in the grating direction) instead of across the grating (e.g., in the lateral direction), according to capillary flow of the fluid 106 along the direction of the channels of the grating that extend in the grating direction. For deeper and/or narrower channels, that effect can be stronger. In contrast, the fluid 106 is less able to flow in the perpendicular direction between channels. That difference in flow may be compensated for by determining particular drop placement locations in the drop pattern. For example, for deep and/or narrow grating channels, the optimal drop pattern may include a larger spacing between the drops in the grating direction, and a closer spacing between the drops in the lateral direction (e.g., as shown in FIG. 5A). Stated somewhat differently, in a flat or other surface that has similar features in both perpendicular directions, the drop pattern may be a square pattern with similar drop spacing along both directions.

In some implementations, the drop size is on the order of tens of microns (e.g., diameter), and the channel width of the grating channels may be less than a micron. The spacing of the drops is dependent on dispenser and/or stage configuration as discussed above. In some examples, given this configuration, the closest the drops can be dispensed is about 10 microns apart, approximately the diameter of the drops. In a dispenser with a multi-nozzle configuration, the nozzle separation in some examples is approximately 100 microns along the printhead direction (e.g., the lateral direction), and this also constrains separation in that direction to about 100 microns. To achieve closer separation in the lateral direction, the stage can be shifted to bring a closer location under the printhead in a subsequent dispense pass. The drop spacing along the direction in which the nozzles are moving relative to the substrate (or vice versa) can be constrained by nozzle firing frequency combined with speed at which the stage can move in that direction. In some examples, the firing frequency range can be 4 kHz to 14 kHz, and the relative speed between the dispenser and substrate where drops need to be dispensed (e.g., the stage movement speed) can be 100 mm/s to 400 mm/s. The imprint speed at which drops are merged into different nanopattern grooves between the template and the substrate can vary from 1 mm/s to 40 mm/s.

The drop pattern determination process can account for the various constraints based on the configuration of the dispense and stage setup, along with the desired nanogeometry of the grating(s) to be created. Other factors can include the volume of fluid 106 to be dispensed, and the desired throughput of the system 100 for manufacturing the eyepieces. For example, multiple stage placements may be possible, but a larger number of steps of moving the stage and dispensing additional drops can increase the time it takes to process each portion of substrate, thus reducing overall throughput of the system. The overall optimal drop pattern may be based on determining which drop pattern leads to the smallest number and/or volume of air gaps, as well as the drop pattern that minimizes the number of passes for dispensing and/or the movements of the stage, to ensure that throughput of the system is in an acceptable range.

In some implementations, a portion (e.g., wafer) of substrate 102 to be imprinted onto may include multiple regions each corresponding to an eyepiece to be cut out of the substrate 102. In such implementations, each eyepiece region may be modeled separately to determine the optimal drop pattern for that region, and the overall dispensing may be according to an overall drop pattern that is a combination of the drop patterns for each region. Alternatively, an eyepiece region may be modeled, and the drop pattern that is determined may be applied to each eyepiece region separately, with the stage 104 moving the substrate 102 between passes to apply the drop pattern to each eyepiece region of the wafer.

As discussed above, the drop patterns can be constrained to certain types of grids (meshes) because of the configuration of the stage and/or nozzles of the dispenser. The drop patterns may also depend on the layout of the wafer of substrate being processed. For example, a wafer can include layouts for four eyepieces (e.g., a 4-up configuration), or a wafer can include layouts for six eyepieces (e.g., a 6-up configuration), e.g., with eyepieces parallel to each other (e.g., a linear array configuration) or rotationally arranged relative to each other (e.g., a pinwheel configuration). This may lead to complications in the modeling. The grid shown in FIG. 4 has vertices separated by lines at 60 degree angles relative to each other, and is based on a 6-up configuration in which each eyepiece is imprinted separately, with the stage 104 rotating (e.g., 60 degrees) between the imprinting of different eyepieces. As another example, a 4-up configuration may lead to a grid that is more of a square pattern. The individual eyepieces in any layout configuration can also be imprinted in a single process step without rotation of wafer and/or stage.

In some implementations, the optimal drop pattern can be determined for a substrate that is to be imprinted, in which a particular eyepiece is divided into different zones. Various zones may have different RLTs and/or different height (or depth) of the nanofeatures that form the grating(s). In some implementations, the imprint may also create transitional zones between zones of different RLT and/or different feature height, and the transitional zones may provide a gradual change (e.g., slope) in the RLT and/or feature height between zones. Such implementations to provide continuously changing gradation patterns are described further below. The drop pattern determining process described above may take such a design into account, and determine the optimal drop pattern to create the multiple zones of differing RLT and/or feature height as well as transitional zones to provide a gradual change in RLT and/or feature height between zones.

### Continuous Gradation Patterns

Implementations also provide for the creation of continuous (e.g., pseudo-gray scale) nano-scale gradation of surface features using inkjet-based nanoimprint lithography. Implementations provide a technique for generating a continuous gradation pattern, within the constraints of the physical apparatus (e.g., inkjet nozzle spacing) and drop volume. Generating a continuous gradation pattern can the grid (e.g., the unit cell mesh) and the drop pattern optimization (e.g., unit cell fluid pattern optimization) described above, as well as unit cell boundary smoothing in some implementations. The continuous gradation jettable pattern can be applied for imprinting nano-patterns and/or micro-patterns over a large area while still keeping the RLT constant, if that is desired. In general, techniques provide for finer control of the RLT over one or more zones being imprinted. Implementations can be used for creating analog continuous gradation patterns in the final imprint, in some instances with an additional etching step to fine-tune the imprinted pattern into the final pattern for the eyepiece. This provides high-efficiency surface relief waveguides with good image uniformity for use in the manufactured optical devices. As discussed above, the optical devices (e.g., waveguides and/or eyepieces) can be used in AR, MR, or VR solutions, or in other types of optics systems.

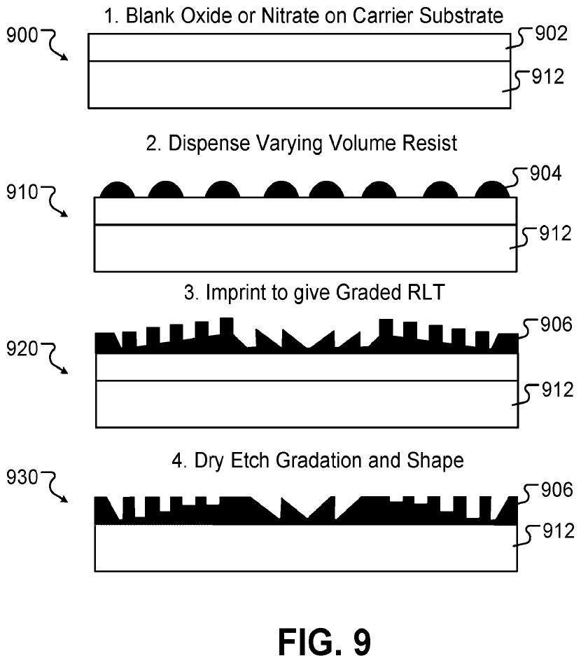

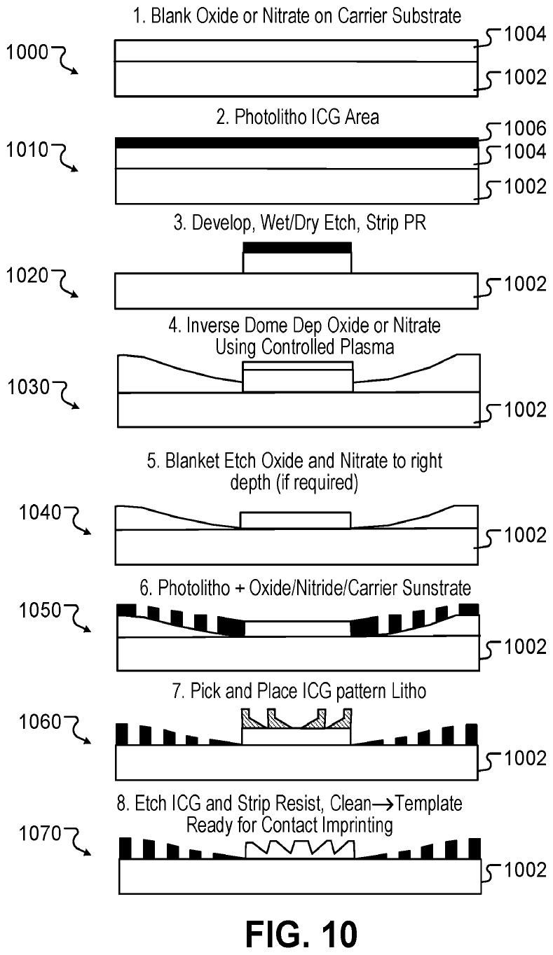

Implementations also provide advantages by (as shown in the example of FIG. 9) creating a substantially continuously varying RLT over a defined region which then can be used to etch a continuous pattern as defined by the RLT into a material such as SiO₂, Si₃N₄, and so forth, for submaster template creation from a template starting with a single depth riding a continuously varying RLT. If a template with features which are continuously varying is fabricated (as shown in FIGS. 10-12) and used to pattern replicate on to suitable substrates (e.g., plastic, glass, etc.) using J-FIL, the drop pattern used can be matched to the continuously varying pattern to be applied to the substrate.

Substrates can be imprinted in multiple zones, and each of the zones may include different surface feature(s) (e.g., diffraction gratings) of different configurations, and/or different RLTs in the various zones. Traditionally, attempts to manufacture waveguides with a fine zone mesh have been limited by two factors. The first factor is inaccuracy in the master template alignment and/or inkjet heads or nozzle alignment in the nanoimprinting tool. The second factor is the feature fabrication accuracy during an etching step. During imprinting from a rigid template or a soft master template (e.g. a CRT) to a substrate (e.g., wafer), the transition area between zones with different grating features (e.g., different discretely graded height and/or linewidth zones) can be filled with a small volume of resist having an uneven RLT, under the pattern that is created by imprinting using the template. Such irregularity in the underlying RLT can cause undesirable optical artifacts that degrade the performance of the finished optical device.

These issues can be mitigated or eliminated by using an analog or at least partly analog continuous gradation pattern, in regions (e.g., transitional zones) of the substrate that are between zones with different gratings and/or different RLTs. Using inkjet imprinting lithography techniques, such as J-FIL, an UV-curable resist (polymer resin) of low viscosity can be dispensed on any suitable type of substrate (e.g., roll, sheet, wafer, rigid, flexible, organic, inorganic, etc.), and the desired (nano-or micro-) patterns can be transferred from a template mold to the substrate quickly with low cost, such as in the processes described above. The drop-on-demand inkjet technique patterns the surface of the substrate with discrete drops according to the previously determined drop (dispense) pattern. One challenge in inkjetting for UV nano-imprint lithography is that the dispensed drops can merge based on a large number of variables, such as the drop volume, contact angle, surface energy, the nanofeatures being created in the grating(s), capillary force, evaporation of the resist fluid, and/or stiffness of template and/or substrate.

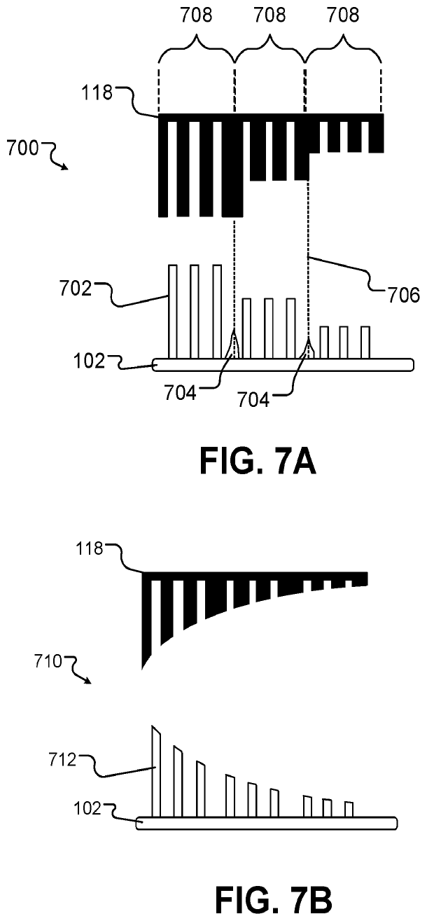

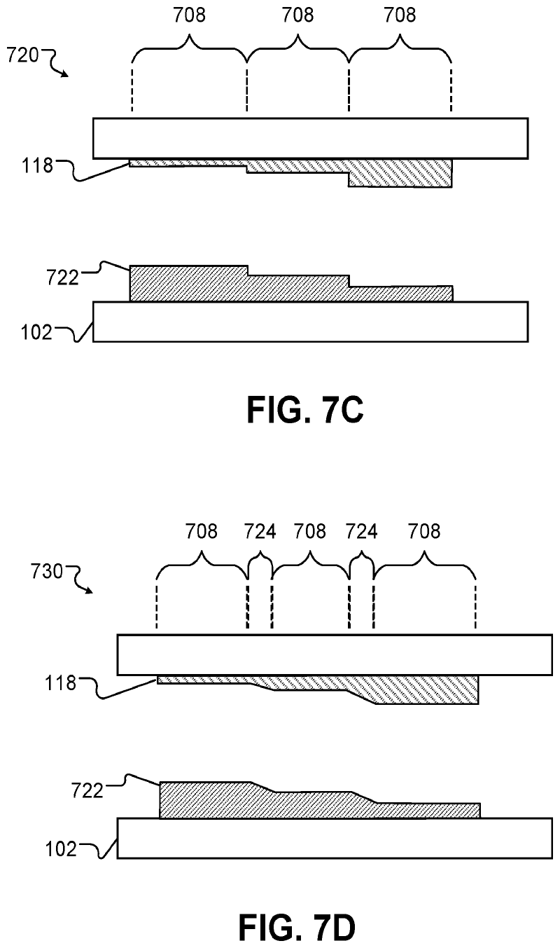

When imprinting from a soft master template to the portion of substrate being processed (e.g., the wafer), the transition area between zones can be filled with a small volume of extra resist. To reduce this artifact, multiple zones can be used in master template designs to reduce the feature height steps between zones. FIG. 7A illustrates such an example in schematic 700. In this example, a template 118 includes multiple zones 708, each with a different grating feature height. Application of the template to the fluid 106 dispensed onto the substrate 102 creates the features 702 for the different zones. At the boundaries 706 between zones, an amount of excess resist fluid 704 can be present following the imprinting. To improve uniformity, and decrease or eliminate the presence of such excess fluid 704, techniques employ a more gradual transition between the zones 708 by using a (e.g., pseudo-gray scale) continuous gradation pattern in the template 118. FIG. 7B illustrates such an example in schematic 710. As shown in this example, the template 118 includes a more continuous variation in feature height, instead of an abrupt transition between zones of different feature heights. The resulting features 712 imprinted on the substrate 102 also exhibit such a continuous variation, without the spikes of excess resist 704 present in the example of FIG. 7A.

In addition to, or instead of, different zones having different feature heights of imprinted gratings, as shown in FIG. 7A, different zones may have different RLTs. FIG. 7C shows an example 720, in which a template 118 includes different zones 708 of different RLT, which can be used to imprint onto a substrate 102 to create imprinted RLTs 722 of different heights in the different zones 708. As described above, such an abrupt transition between zones of different RLT can lead to adverse optical effects in the optical device. To avoid such adverse effects, the transition between zones may be more gradual, as shown in example 730 of FIG. 7D. In this example, the zones 708 of different RLT are interposed with transitional zones 724 in which the RLT changes somewhat more gradually between the zones of different RLT.

In addition to the benefit of smoother imprinting transition and relaxed alignment requirements, this can also allow for use of a finer grid in the optical design and provide a method for fabrication of a continuous master template. When the templates and/or master templates having a master pattern which is desired to be replicated have discrete zones, the alignment requirement between drop dispense and template to substrate registration may be more stringent. This is because a drop volume for a region which takes lower volume of the fluid may not be in a region with a higher drop volume requirement. In some instances, the separation between zones can be in the range of 100 nm to 1 micron. For drops sizes on the order of 100 s of microns, the process may be fined tuned based on fluid spread and alignment. For example, when the transition between two such zones is smoother, e.g., the transition zone is about 10-1000 microns wide, then the drop spread is not abruptly changing and gives a smoother transition in RLT as well as maintaining the desired RLT range.

The use of such gradation enhances virtual image brightness (e.g., efficiency) without sacrificing image uniformity (e.g., how well the image fills the corners of the field of view versus the center). However, if gradation in templates is created using photolithography with etch masking, the boundary between two gradation step zones can cause the RLT to be altered over a wider area (e.g., ˜10-100 microns) compared to the zone transition boundary (e.g., <1 micron). In particular, a volume of the resist can enter a shallower neighboring zone, thus raising the RLT of that neighboring zone. Similarly, the resin volume from the shallow zone can cause a thinner RLT and/or non-fill in the taller neighboring zone.

The zones described herein may be on one surface or both surfaces of the substrate. In some examples, different zones are non-overlapping, such that the zones are separate from one another. Alternatively, different zones may at least partly overlap. Different zones may be adjacent or separated by some suitable distance. Zones may be of any reasonable shape and/or size, with any suitable dimensions to cover a portion of the area of at least one surface of the substrate.

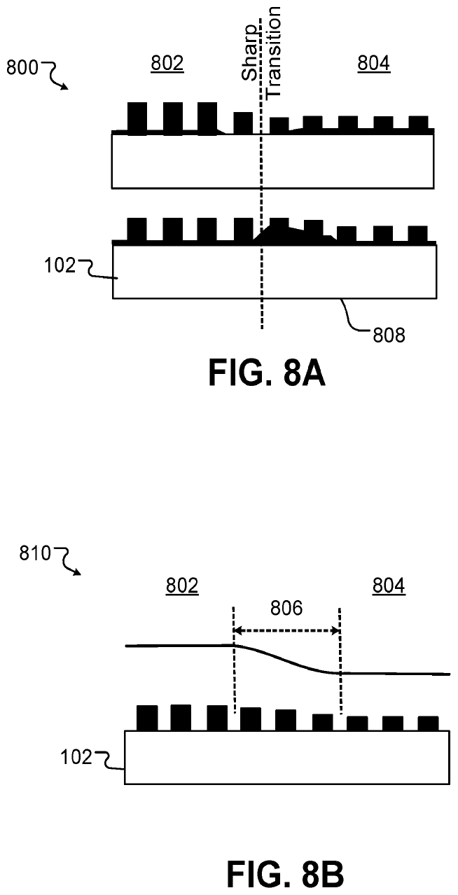

FIG. 8A depicts a schematic 800 showing an example in which different zones 802 and 804 of surface features on the substrate 102 have features of different heights and/or different RLTs, and in which a portion 808 of the resin fluid has flowed from one zone into another across the sharp (e.g., abrupt, discontinuous) transition boundary between zones. FIG. 8B depicts a schematic 810 showing an example in which a transition area 806 has been created between the zones of different feature height. In the transition area 806, the feature height changes more gradually between the higher feature zone 802 and the lower feature zone 804, avoiding the undesired flow of resin 808. Test results have shown improvement in image uniformity in designs created as in the second example of FIG. 8B. In the example of FIG. 8A, test results show the presence of unwanted high-frequency artifacts in the finished optical device. Such predominant high frequency image striations can be undesirable and very hard to color correct in a final device and/or over large number of devices as these striations may not always appear in the same location. A gradation pattern such as in FIG. 8B can mitigate or eliminate such artifacts, providing an analog zone transition region where the eyebox efficiency is the same but with improved contrast and sharpness.

Generating a continuous gradation pattern employs the grid (e.g., unit cell mesh) and drop pattern optimization (e.g., unit cell fluid pattern optimization) described above, as well as such unit cell boundary smoothing. Techniques such as J-FIL are suitable for such gradation as they can dispense a targeted drop volume over a large area in which, for example, the resist volume can increase (or decrease) gradually from one side of the dispense area to the other. In some implementations, a random or quasi-random drop pattern may be used to fill a particular region, such as a region that is the CPE of an eyepiece. Using a random drop pattern to gradually modulate the resist volume dispensed to match the grating depth in the region, the zone boundaries as defined by the drop pattern may not be noticeable, due to the analog gradation defined in the imprint. In some implementations, the drop pattern can be further optimized using the drop spreading ratio in each unit cell as a function grating orientation, feature height, dispense resist type, and/or substrate type, to better reduce or eliminate the presence of non-fill defects. The entire wafer may be meshed into small unit cells, and the feature geometry (including residue layer thickness, grating duty cycle, feature height profile, grating orientation, etc.), unit cell size, and drop volume determine the number of drops inside each unit cell. The calculated drop number can be provided as input to a Centroidal Voronoi Tessellations (CVT) loop for location optimization. CVT is a particular type of Voronoi tessellation in which the generating point of each Voronoi cell is also its centroid (e.g., the center of mass). It can be viewed as an optimal partition corresponding to an optimal distribution of generators. The distribution of drops can reach a local minimum location in the CVT loop with enough iterations and sufficiently high resolution. A unit cell can be defined as a repeating drop pattern which can be placed on to an underlying grid pattern, which can be defined by the various tooling constraints such as those described herein, including drop nozzle spacing, dispense frequency, dispense speed, and so forth.

The optimized unit cells for different feature heights are similar to mosaics with different thickness across the boundaries. If the mesh (e.g., grid) is fine enough and the unit cell size is small enough, the thickness difference can be ignored for an imprinting with desired low resolution. However, with a given number of drops and fixed drop volume in the unit cell, the mesh fineness is limited. As a result, for high resolution imprinting, other methods may be used to optimize the patterns. To smooth the boundaries across different unit cells, drop locations can randomized across a range, with the original determined drop location as the center in both X- and Y-directions. Then the randomized patterns can be transferred to the entire wafers. After imprinting and optical measurement, the drop patterns may be adjusted and optimized again based on the measurement feedback. Accordingly, such randomization, measurement, and re-randomization can be performed as a modification of the process of FIG. 3.

A graded RLT imprint can also be used in the fabrication of a template (e.g., sub-master) with a corresponding gradation trend defined primarily by the drop pattern dispensed and imprinted on. Etching may also be employed in the process. The gradation etch into, for example SiO₂ (thermal oxide over Si), can be performed secondarily with the RLT acting as an etch cover when using a dry etch RIE technique for etching SiO₂. Etch selectivity can be controlled with modulating gases such as CHF₃, CF₄, C₄F₈, Ar, O₂, SF₆, etc. for etching either an organic imprint or SiO₂. In this way, a template can be fabricated to include multi-step zones with an analog zone transition and/or an analog gradation pattern, to provide a master mold ready for replication. Tuning the resist volume dispensed to the various zones can enable different depths to be dry etched into the template material (e.g., SiO₂, Si₃N₄, Si, etc.). Using lithography techniques such as J-FIL to create the template also enables transfer of various geometries such as Sawtooth, multi-step, etc. during the dry etch process.

This process can significantly reduce the cost and complexity of etching various sizes of wafer templates (e.g., two, four, six, eight, twelve inches, and so forth) used in the lithography. Using an imprint process with drop-on-demand dispense of curable resist (as in J-FIL), a dispense pattern with a random or quasi-random drop location and/or a multi-zone (e.g., eight or more zones) drop pattern for example, can be dispensed or coated over a targeted waveguide substrate to transfer the waveguide pattern from the master mold.

FIG. 9 shows an example process for fabricating a complex (e.g., 6-up) template with analog (or at least partly analog) gradation and/or other particular nano-features. At 900, a carrier substrate 912 with an overlay of blank oxide or nitride material 902 is provided. At 910, drops of resist 904 are dispensed onto the overlay 902, such as according to a drop pattern described herein. At 920, the resist is imprinted to provide a pattern 906 with graded RLT as shown. At 930, dry etching is performed to etch down the pattern 906 into a final pattern 908. As shown in the example of FIG. 9, the etching can create the final pattern 908 that can have a substantially flat or level upper height across the various features that may have different feature depths relative to a graded RLT.

Surface features can include multiple zones that each have a different RLT and/or different patterns with features of different heights/depths. Implementations provide for the use of such zones, but with a gradual change in RLT and/or feature height between zones, as described herein to mitigate the various negative effects that may occur because of the abrupt changes between zones. Example RLTs may be in the range of 10-35 nanometers (nm). Feature creation can also include a step of etching the features following dispense and imprinting using a template. Previously available methods that use imprint plus etching can be costly due to the extra etching step. The implementations described herein for drop pattern optimization can reduce the cost, by providing for an initially imprinted pattern that is more accurate and/or closer to the final pattern than would otherwise be created without use of an optimized drop pattern. Etching can then be employed to fine-tune the pattern and bring it into its final form. Use of an optimized drop pattern can also eliminate the need for performing one or more additional imprinting steps using sub-master template(s).

The algorithm described above to determine the optimized drop pattern can also take into account the boundary areas in which the transition between zones is gradual in RLT change and/or feature height change. For example, as shown in FIG. 8, the volume dispensed for zones 802 and 804 may be different, and the transition zone 806 can have a drop pattern where the drops towards 804 are spaced further apart than the drops toward 802. Drop volume is generally controlled by drop size, number of drops, drop density across the transition zone (e.g., along the X-Y pitch), and so forth.

As discussed above, continuous analog gradation or analog transition between zones of different RLT and/or surface feature height is useful to enable high efficiency and uniform images in optical devices that employ planar waveguides with relief nano-structures. The techniques described herein can also be used for curved waveguides, and provide similar advantages. Such gradation avoids otherwise sharp transitions between zones which can cause reduced image uniformity and lowered contrast plus sharpness (due to variation in RLT). Use of such gradations can also avoid the increased complexity and manufacturing cost of template fabrication, while achieving similar eyebox efficiency targets in the manufactured eyepieces. Implementations provide for the fabrication of such a template for nano-imprint lithography, using plasma controlled deposition with etch methods. Resulting advantages include reduced template gradation complexity in manufacturing and cost, reduced non-uniformity in the resulting image displayed through the eyepiece, and improved image quality (e.g., in contrast and sharpness) using J-FIL techniques to create the final pattern on the waveguide substrate.

FIG. 10 illustrates an example process for fabricating imprint templates with analog graduation using a deposition and etch approach. This process enables a smooth transition between zones of different feature heights without the use of multiple masking, lithography, and etching steps which would otherwise be needed for fabrication of such a multi-zone master template. For analog gradation using the previously available step-wise photo-litho exposure process, the number of steps would be extremely large and costly.

Similarly to the example of FIG. 9, at 1000 a carrier substrate 1002 with an overlay of blank oxide or nitride 1004 is provided. At 1010, photolithography can be performed to create a region 1006. The top region 1006 can be a spincoated photoresist to create area(s) that are not to be etched or removed in the subsequent steps.

At 1020, operations are performed to develop, wet or dry etch, and strip a portion of the photoresist. At 1030, operations are performed to create an inverse dome shaped deposition profile in the oxide/nitride layer using controlled plasma. At 1040, in some examples, blank etching can be performed to reduce the remaining overlay (e.g., oxide or nitride) profile to a desired depth. Blank etching can be done using a wet (e.g. using buffered oxide etch or HF for SiO₂, etc.) or a dry (e.g., RIE, ICP-RIE, IBE, etc.) etch process. At 1050, photolithography can be performed to create desired features in the oxide/nitride carrier substrate. The lithography is not limited to photolithography, but electron beam lithography or UV/thermal nanoimprint lithography can also be used. At 1060, lithography step such as UV nanoimprint lithography can be performed to provide a pattern (e.g., ICG pattern). At 1070, the pattern can be etched and at least a portion of the resist can be stripped to prove the template that is suitable for imprinting on the waveguide substrate to create the patterned waveguide(s).

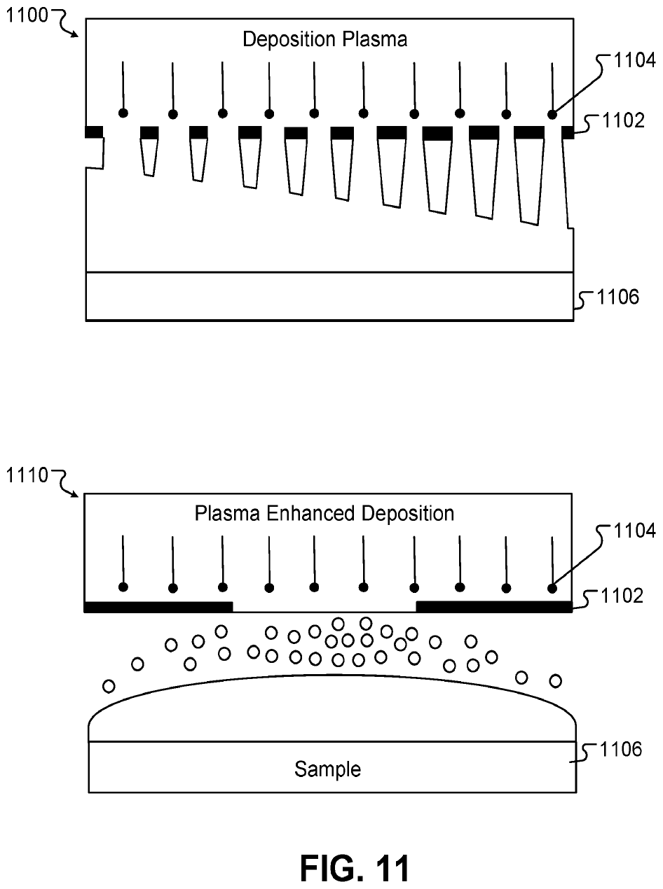

The method can be used to make an inverse dome or normal dome shaped deposition profile, and a shadow mask is used to either mask the deposition material density or change the plasma density for plasma enhanced deposition processes such as plasma enhanced chemical vapor deposition (PE-CVD). FIG. 11 illustrates examples of the method to create a dome or inverse dome shape over a substrate by manipulating the deposition with shadow masks in the plasma head or deposition source. Example materials used in the deposition can include, but are not limited to, SiO₂, Si₃N₄, or Al₂O₃. As shown in example 1100, a shadow mask 1102 with varying diameter holes can be used, and deposition plasma 1104 can pass through the holes in the mask onto a sample 1106. In example 1110, a shadow mask 1102 is employed, with changing density of the plasma-enhanced deposition density. The hole location and density governs how much plasma and chemical reactants are exposed to different regions and thus chemically react to deposit or in the case of etch be removed.

Implementations also provide for a continuous gradation method using a subtractive gradated etched substrate to generate continuous gradation templates, which can improve field of view uniformity and optimize eyepiece efficiency. Previous techniques involve the creation of flat top, and gradated bottom, nano-patterns on templates. Implementations improve on this technique by creating flat bottom, and gradated top, nano-patterns on templates. This can avoid RLT non-uniformity on the imprinted resist, and improve the field of view uniformity.

When the master template has patterned features with a flat top and a step bottom, the CRT made from the master template accordingly has a step surface. When this CRT is used to imprint on (e.g., glass) substrates to generate an eyepiece, the steps cause the creation of RLT humps at the step transaction area, as discussed above. This can cause field of view uniformity artifacts.

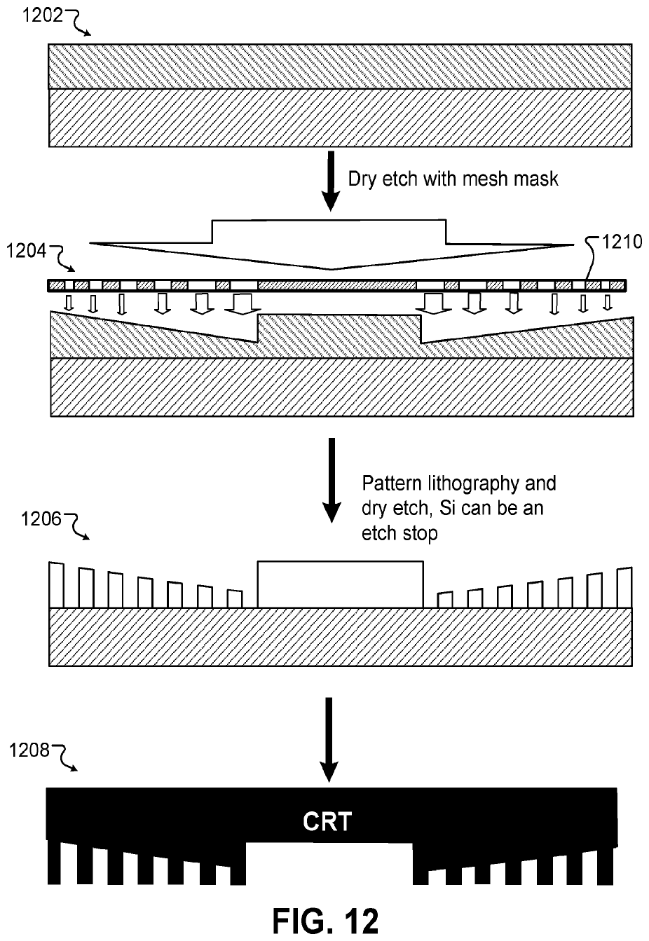

FIG. 12 shows an example process for creating a template using subtractive continuous gradation. As shown at 1202, a substrate having a Si layer and a SiO₂ layer is received. A mesh shadow mask 1210 is put on the top of the wafer during dry SiO₂ etch. By tuning the mesh mask opening duty cycle, the etch rate is tuned and the SiO₂ layer thickness gradation is created, as shown at 1204. In this operation, a higher etch rate provides thinner SiO₂ layer ends. During the pattern dry etch, the Si can layer can act as an etch stop, such that the feature depth stops at the SiO₂-Si interface, as shown in 1206. Thus, the patterned feature has a flat bottom. The CRT made from this template can have a flat surface, as shown at 1208. In some examples, the center plateau on the template is far from the pattern area, so it may not affect the pattern area imprinting. The mesh shadow mask etching gradation method is further described in a U.S. Pat. No. 10,527,865, titled “Method and System For Tunable Gradient Patterning Using a Shadow Mask,” the entirety of which is incorporated by reference into the present disclosure.

### Example Computing System

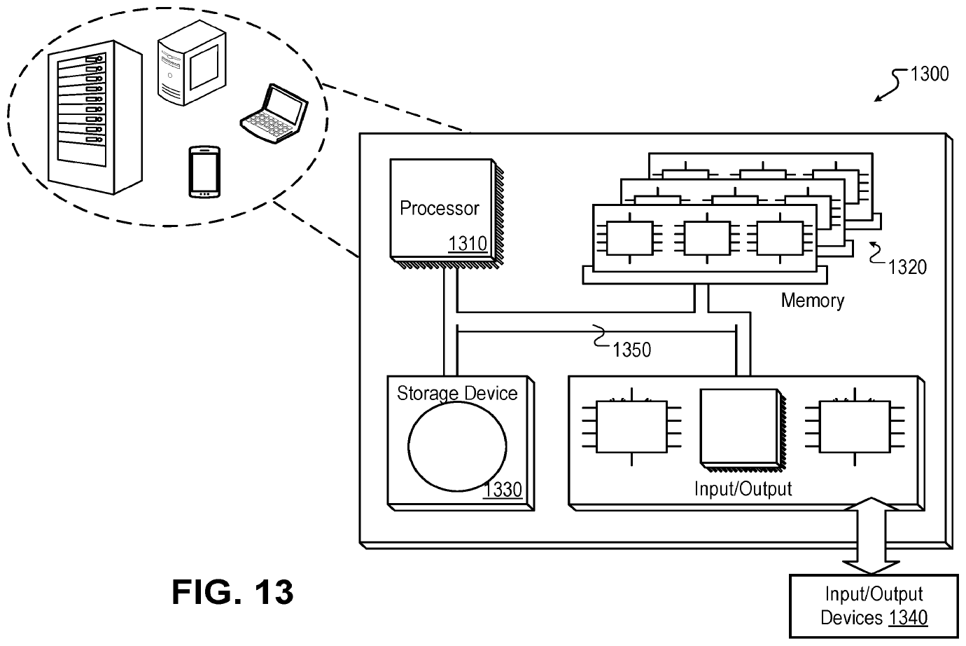

FIG. 13 illustrates a schematic diagram of an example computer system 1300. The various computing devices described herein, such as the control device 120 shown in FIG. 1, can be implemented to include one or more of the components of system 1300.

The system 700 includes one or more processors 1310, a memory 1320, a storage device 1330, and input/output device(s) 1340. Each of the components 1310, 1320, 1330, and 1340 can be interconnected using one or more system busses 1350. The processor(s) 1310 are capable of processing instructions for execution within the system 700. The processor(s) 1310 can include single-threaded processor(s) and/or multi-threaded processor(s). The processor(s) 1310 are capable of processing and executing instructions stored in the memory 1320 and/or on the storage device 1330 to perform various operations, receiving and analyzing data input, generating data output, storing and retrieving data, presenting textual, graphical, audio, video, image(s), and/or other types of information through a user interface on the input/output device 1350, and so forth.

The memory 1320 stores information within the system 700. In some implementations, the memory 1320 is a computer-readable medium. In some implementations, the memory 1320 is a volatile memory unit. In some implementations, the memory 1320 is a non-volatile memory unit.

The storage device 1330 provides mass storage for the system 700. In some implementations, the storage device 1330 is a computer-readable medium. In various different implementations, the storage device 1330 may be a floppy disk device, a hard disk device, a solid state drive, an optical disk device, a tape device, universal serial bus stick, and/or some other suitable type of storage device.

The input/output device(s) 1350 provide input/output operations for the system 700. The input/output device(s) 1350 can include input devices including, but not limited to, a keyboard, a pointing device, a mouse, a touchpad, a camera, a microphone, an orientation or movement sensor (e.g., accelerometer, gyroscopic sensor, etc.), and/or a game controller. The input/output device(s) 1350 can also include output devices including, but not limited to, a display, an audio speaker, a haptic actuator, a printer, and so forth.

The features described can be implemented in digital electronic circuitry, or in computer hardware, firmware, software, or in combinations of them. The apparatus can be implemented in a computer program product tangibly embodied in an information carrier, e.g., in a machine-readable storage device, for execution by a programmable processor; and method steps for the methods described herein can be performed by a programmable processor executing a program of instructions to perform functions of the described implementations by operating on input data and generating output. The described features can be implemented advantageously in one or more computer programs that are executable on a programmable system including at least one programmable processor coupled to receive data and instructions from, and to transmit data and instructions to, a data storage system, at least one input device, and at least one output device. A computer program is a set of instructions that can be used, directly or indirectly, in a computer to perform a certain activity or bring about a certain result. A computer program can be written in any suitable programming language, including compiled or interpreted languages, and it can be deployed in any form, including as a stand-alone program or as a module, component, subroutine, library, or other unit suitable for use in a computing environment. A module is one or more computer programs and/or portion(s) of computer program(s) that is executable by one or more processors.

Suitable processors for the execution of a program of instructions include, by way of example, both general and special purpose microprocessors, and the sole processor or one of multiple processors of any kind of computer. Generally, a processor can receive instructions and data from a read-only memory or a random access memory or both. The elements of a computer are a processor for executing instructions and one or more memories for storing instructions and data. Generally, a computer may also include, or be operatively coupled to communicate with, one or more mass storage devices for storing data files. Such devices can include magnetic disks, such as internal hard disks and removable disks, magneto-optical disks, and/or optical disks. Storage devices suitable for tangibly embodying computer program instructions and data include any suitable form of non-volatile memory, including by way of example semiconductor memory devices, such as erasable programmable read-only memory (EPROM), electrically erasable programmable read-only memory (EEPROM), flash memory devices, magnetic disks such as internal hard disks and removable disks, magneto-optical disks, and compact disk read-only memory (CD-ROM) and digital video disk read-only memory (DVD-ROM) disks. The processor and the memory can be supplemented by or incorporated into one or more application-specific integrated circuits (ASICs).

To provide for interaction with a user, the features can be implemented on a system having a input/output device(s), such as a display device. Display devices can include any suitable type of display, such as cathode ray tube (CRT), liquid crystal display (LCD), and so forth, for displaying information to the user. Input device(s) such as a keyboard and/or a pointing device such as a mouse or a rail trackball can enable user input to the system.

The features can be implemented in a computer system that includes a back-end component, such as a data server, or that includes a middleware component, such as an application server or an Internet server, or that includes a front-end component, such as a client computer having a graphical user interface or an Internet browser, or any combination of them. The components of the system can be connected by any form or medium of digital data communication such as a communication network. Examples of communication networks include, e.g., a local area network (LAN), a wide area network (WAN), and the computers and networks forming the Internet.

The computer system can include clients and servers. A client and server are generally remote from each other and typically interact through a network, such as those discussed herein. The relationship of client and server arises by virtue of computer programs running on the respective computers and having a client-server relationship to each other. The servers may be part of a cloud, which may include ephemeral aspects.

While this disclosure contains many specific implementation details, these should not be construed as limitations on the scope of any implementation of the present disclosure or of what may be claimed, but rather as descriptions of features specific to example implementations. Certain features that are described in this specification in the context of separate implementations can also be implemented in combination in a single implementation. Conversely, various features that are described in the context of a single implementation can also be implemented in multiple implementations separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. In addition, the processes depicted in the figures do not necessarily require the particular order shown, or sequential order, to achieve desirable results. In certain implementations, multitasking and parallel processing may be advantageous.

While various implementations of the present invention have been described herein, it should be understood that they have been described as examples. Many variations and modifications may be apparent to those skilled in the art upon reading the specification. The breadth and scope of the present invention is not limited by the examples described herein, and can be interpreted broadly to include such variations and modifications. The described implementations and other such implementations are within the scope of the following claims.

1. A method performed by a system for manufacturing optical devices, the method comprising:
determining a dispense pattern to dispense drops of photoresist to form one or more surface features on at least one surface of a substrate, wherein determining the drop dispense pattern includes:
determining a grid of available drop locations, based at least partly on one or more drop location constraints, wherein the one or more drop location constraints are based on a configuration of one or more of: i) a dispenser component of the system, which dispenses the drops of photoresist, or ii) a stage component of the system, which stabilizes the substrate during dispensing;
for each candidate dispense pattern of a plurality of candidate dispense patterns, predict a spread pattern of the drops dispensed according to the respective candidate dispense patterns to provide a plurality of predicted spread patterns, wherein each of the plurality of candidate dispense patterns includes a subset of the available drop locations, and wherein each predicted spread pattern is based at least partly on the one or more surface features to be formed on the at least one surface of the substrate; and
determine an optimal dispense pattern from among the plurality of predicted spread patterns;
dispensing the drops of photoresist, according to the optimal dispense pattern, onto the at least one surface of the substrate or onto a template usable to mold the one or more surface features;
applying the template to mold the dispensed photoresist into the one or more surface features on the at least one surface of the substrate;
curing the dispensed photoresist to form the one or more surface features; and
singulating the substrate to create an optical device that includes the one or more surface features.

2. The method of claim 1, wherein the substrate is composed of a glass or a polymer.

3. The method of claim 1, wherein the photoresist is a polymer fluid.

4. The method of claim 1, wherein curing the photoresist includes one or more of applying ultraviolet radiation to the dispensed photoresist, or applying heat to the dispensed photoresist.

5. The method of claim 1, wherein the one or more surface features include one or more diffraction gratings.

6. The method of claim 5, wherein the one or more diffraction gratings include one or more of an in-coupling grating (ICG), an orthogonal pupil expander (OPE), an exit pupil expander (EPE), or a combined pupil expander (CPE).

7. The method of claim 1, wherein the one or more constraints include one or more of the following: a number of nozzles of the dispenser component, a spacing between the nozzles of the dispenser component, and a range of dispense frequencies of the nozzles of the dispenser component.

8. The method of claim 1, wherein the one or more constraints include one or more of the following: a range of movement speeds of the stage component, and available directions of movement of the stage component.

9. The method of claim 1, wherein determining the dispense pattern that corresponds to the optimal spread pattern includes identifying the optimal spread pattern that minimizes one or more of the following: a number of void gaps in the spread pattern, a size of the void gaps in the spread pattern, and a total volume of the void gaps in the spread pattern.

10. The method of claim 1, wherein:
the at least one surface of the substrate includes a first zone and a second zone that is non-overlapping with the first zone; and
the one or more surface features include a first set of surface features in the first zone and a second set of surface features in the second zone.

11. The method of claim 10, wherein:
the first set of surface features includes a first residual layer of the photoresist having a first residual layer thickness (RLT) in the first zone; and
the second set of surface features includes a second residual layer of the photoresist having a second RLT in the second zone, the second RLT being different than the first RLT.

12. The method of claim 11, wherein:
the at least one surface of the substrate includes a third zone between the first zone and the second zone; and
the third zone includes a third residual layer of the photoresist having a gradated RLT that varies continuously from the first RLT near a boundary of the third zone with the first zone to the second RLT near the boundary of the third zone with the second zone.

13. The method of claim 10, wherein:
the first set of surface features includes first nanostructures having a first height relative to the at least one surface; and
the second set of surface features includes second nanostructures having a second height relative to the at least one surface.

14. The method of claim 13, wherein:
the at least one surface of the substrate includes a third zone between the first zone and the second zone; and
the third zone includes third nanostructures having a height that varies continuously from the first height near the boundary of the third zone with the first zone to the second height near the boundary of the third zone with the second zone.

15. The method of claim 1, wherein the optical device is a waveguide.

16. The method of claim 1, wherein the one or more surface features are on one surface of the substrate.

17. The method of claim 1, wherein the one or more surface features are on more than one surface of the substrate.

18. The method of claim 1, wherein the one or more surface features include at least one non-diffractive pattern.

19. The method of claim 18, wherein the one or more surface features include an anti-reflective pattern.
